(19) United States
(12) Patent Application Publication
(10) Pub. No.: US 2018/0292471 A1
(43) Pub. Date: Oct. 11, 2018

(54) DETECTING A MECHANICAL DEVICE USING A MAGNETOMETER AND AN ACCELEROMETER

(71) Applicant: Intel Corporation, Santa Clara, CA (US)

(72) Inventors: Ke-Yu Chen, San Jose, CA (US); Rahul C. Shah, San Francisco, CA (US); Lama Nachman, Santa Clara, CA (US); Jonathan Huang, Pleasanton, CA (US)

(73) Assignee: Intel Corporation, Santa Clara, CA (US)

(21) Appl. No.: 15/481,414

(22) Filed: Apr. 6, 2017

(51) Int. Cl. G01R 33/07; G01S 19/42; G01S 19/26; G01C 21/16; B60W 40/12

(52) U.S. Cl. CPC G01R 33/072; G01S 19/426; B60W 40/12; G01C 21/16; G01S 19/26

(57) ABSTRACT

A technology is described for detecting a mechanical device. An example method may include retrieving magnetometer data generated by a magnetometer coupled to a mobile device. Magnetic features may be extracted from the magnetometer data, where the magnetometer data may be associated with magnetic field distortion patterns generated by mechanical motions of a mechanical device. Accelerometer data generated by an accelerometer coupled to the mobile device may be retrieved. Acceleration features associated with vibration patterns generated by the mechanical motions of the mechanical device may be extracted from the accelerometer data. Thereafter, the mechanical device may be identified using the magnetic features and the acceleration features.

### BACKGROUND

Understanding human activities may be beneficial to constructing a smart environment that includes sensors, actuators, displays, and computational elements that are embedded into everyday objects, and are seamlessly connected through a continuous network. Low-cost, easily accessible sensing modalities for human activity can be used for monitoring and inferencing human activity. For example, mobile devices have become ubiquitous and may be a part of a person's daily life. Sensors built into mobile devices offer a great opportunity to detect human activity using the sensing platform provided by the mobile devices. Human activity detected by mobile devices may benefit applications, such as personal healthcare applications, life coaching applications, or recommender systems, which may be configured to analyze the human activity.

One specific type of context associated with human activity is a mode of transportation, namely, a modality used by a person to travel from one point to another. In particular, recognizing human-powered and motorized forms of transportation may be beneficial for contextually-aware applications. As an example, a personal assistant application may use information related to a mode of transportation to understand that a person took public transit to travel to work. As another example, a life coaching application may use information related to a mode of transportation to make suggestions, such as getting off the bus one stop earlier in order to increase physical activity.

### BRIEF DESCRIPTION OF THE DRAWINGS

Features and advantages of invention embodiments will be apparent from the detailed description which follows, taken in conjunction with the accompanying drawings, which together illustrate, by way of example, invention features; and, wherein:

FIG. 1 is a diagram illustrating a high-level example of a system for detecting a mechanical device.

FIG. 2 is a block diagram that illustrates components of an example mobile device on which the present technology may be executed.

FIG. 3 is a block diagram illustrating an example system for detecting a mechanical device using sensor data sent by a mobile device.

FIG. 4 is a flow diagram that illustrates an example method for detecting a mode of transportation using a mobile device configured with a magnetometer and an accelerometer.

FIG. 5 illustrates example line graphs showing example frequencies from a magnetometer that infer a vehicle type.

FIG. 6 illustrates example line graphs showing magnetic field variations detected by a magnetometer included in a mobile device when placed at different locations in a vehicle.

FIG. 7 illustrates example line graphs showing example power spectrums of vertical acceleration for a plurality of vehicles.

FIG. 8 illustrates a histogram showing example Gaussian distributions for a vertical component and a horizontal component of acceleration data transformed to the frequency domain.

FIG. 9 illustrates example line graphs showing example magnetic field variations for appliances.

FIG. 10 illustrates example confusion matrices for different vehicle configuration scenarios in which a location of a mobile device can be determined.

FIG. 11 is a flow diagram illustrating an example method for detecting a mechanical device.

FIG. 12 is block diagram illustrating an example of a computing device that may be used to execute a method for detecting a mode of transportation.

### DESCRIPTION OF EMBODIMENTS

Before invention embodiments are described, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular examples or embodiments only and is not intended to be limiting. The same reference numerals in different drawings represent the same element. Numbers provided in flow charts and processes are provided for clarity in illustrating steps and operations and do not necessarily indicate a particular order or sequence.

Furthermore, the described features, structures, or characteristics can be combined in any suitable manner in one or more embodiments. In the following description, numerous specific details are provided, such as examples of layouts, distances, network examples, etc., to provide a thorough understanding of various invention embodiments. One skilled in the relevant art will recognize, however, that such detailed embodiments do not limit the overall inventive concepts articulated herein, but are merely representative thereof.

As used in this written description, the singular forms “a,” “an” and “the” include express support for plural referents unless the context clearly dictates otherwise. Thus, for example, reference to “a network” includes a plurality of such networks.

Reference throughout this specification to “an example” means that a particular feature, structure, or characteristic described in connection with the example is included in at least one invention embodiment. Thus, appearances of the phrases “an example” or “an embodiment” in various places throughout this specification are not necessarily all referring to the same embodiment.

As used herein, a plurality of items, structural elements, compositional elements, and/or materials can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various invention embodiments and examples can be referred to herein along with alternatives for the various components thereof. It is understood that such embodiments, examples, and alternatives are not to be construed as defacto equivalents of one another, but are to be considered as separate and autonomous representations under the present disclosure.

Furthermore, the described features, structures, or characteristics can be combined in any suitable manner in one or more embodiments. In the following description, numerous specific details are provided, such as examples of layouts, distances, network examples, etc., to provide a thorough understanding of invention embodiments. One skilled in the relevant art will recognize, however, that the technology can be practiced without one or more of the specific details, or with other methods, components, layouts, etc. In other instances, well-known structures, materials, or operations may not be shown or described in detail to avoid obscuring aspects of the disclosure.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in this written description, like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that any terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

As used herein, comparative terms such as “increased,” “decreased,” “better,” “worse,” “higher,” “lower,” “enhanced,” and the like refer to a property of a device, component, or activity that is measurably different from other devices, components, or activities in a surrounding or adjacent area, in a single device or in multiple comparable devices, in a group or class, in multiple groups or classes, or as compared to the known state of the art. For example, a data region that has an “increased” risk of corruption can refer to a region of a memory device which is more likely to have write errors to it than other regions in the same memory device. A number of factors can cause such increased risk, including location, fabrication process, number of program pulses applied to the region, etc.

Numerical amounts and data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

### EXAMPLE EMBODIMENTS

An initial overview of technology embodiments is provided below and specific technology embodiments are then described in further detail. This initial summary is intended to aid readers in understanding the technology more quickly, but is not intended to identify key or essential technological features, nor is it intended to limit the scope of the claimed subject matter.

A technology is described for detecting a mechanical device using sensor data provided by a magnetometer and an accelerometer. In one example, a magnetometer may act as a Hall-effect sensor that detects magnetic field distortions caused by mechanical motions of a mechanical device. For example, the mechanical motions of a moving vehicle may yield observable distorted magnetic fields for which the magnetometer may detect. The distortion may be harmonically synchronous with a vehicle's moving components, such as rotations in the vehicle's wheels and transmission gears, which may be manifested as alternatingly changing (AC) magnetic signals. The magnetic distortions may be captured in magnetometer data generated by the magnetometer.

The accelerometer may be used to capture vibrations or other motion associated with a mechanical device. For example, accelerometer data generated by the accelerometer may be analyzed to identify mechanical device vibrations captured by the accelerometer. For example, different types of vehicles produce distinctive vibration patterns, and these vibration patterns can be used to detect a vehicle used as a mode of transportation. In one example, a moving vehicle may impact accelerometer data generated by the accelerometer by how a vehicle accelerates and decelerates between stationary states and vibration patterns that correlate to how a vehicle absorbs vibrations from a surface on which the vehicle travels (e.g., road, track, or air).

The mechanical device may be detected using both the magnetometer data and the accelerometer data generated by the magnetometer and the accelerometer. By using both the magnetometer data and the accelerometer data, shortcomings that may be associated with one sensor may be overcome by the other sensor. In one example, magnetic features associated with magnetic field distortion patterns generated by mechanical motions of a mechanical device may be extracted from the magnetometer data, and acceleration features associated with vibration or movement patterns generated by the mechanical motions of the mechanical device may be extracted from the accelerometer data. The magnetic features and the acceleration features can then be input to a classifier, which may be configured to evaluate the magnetic features and the acceleration features and output a classification that corresponds to the magnetic features and the acceleration features. In the case that the magnetic features and the acceleration features are associated with a vehicle, the classification output by the classifier may be for a vehicle type, thereby inferring a mode of transportation utilized by a user of a mobile device having a magnetometer and accelerometer that captured the magnetometer and accelerometer data.

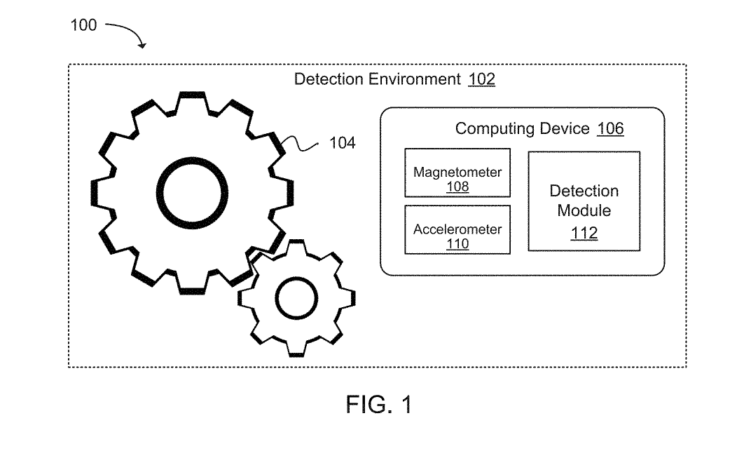

To further describe the technology, examples are now provided with reference to the figures. FIG. 1 is a diagram illustrating a high level example of a system 100 for detecting a mechanical device 104 using a magnetometer 108 and an accelerometer 110 included in a computing device 106 located within a detection environment 102. A mechanical device 104 may include any device having mechanical components that, when activated, cause a magnetic field distortion that can be detected by a magnetometer 108. For example, the mechanical components may include, but are not limited to, engines, motors, transmissions, alternators, differentials, gears, wheels, fans, as well as other types of mechanical components.

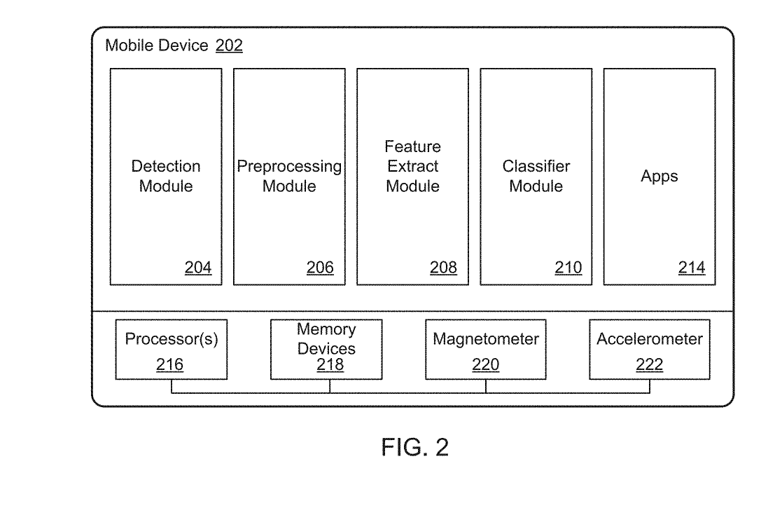

In the example illustrated, the computing device 106 may include a magnetometer 108, an accelerometer 110, and a detection module 112. The computing device 106 may comprise a mobile device, such as a smart phone, wearable computer (e.g., smartwatch, fitness tracker, and smart glasses), tablet computer, laptop or notebook computer, and the like. When located within a detection environment 102, data generated by the magnetometer 108 and the accelerometer 110 may be analyzed by the detection module 112 to determine a classification for the mechanical device 104. For example, the detection module 112 may be configured to determine what type of vehicle (e.g., a bicycle, motorcycle, automobile, bus, train, airplane, etc.) and/or what type of appliance (e.g., hair dryer, fan, electric shaver, cell phone, washer and dryer machines, etc.) may be located within the detection environment 102. The detection module 112 is described in greater detail below in association with FIG. 2.

A detection environment 102 may comprise an area or space within which a magnetometer 108 may be able to detect distortions in a magnetic field caused by a mechanical device 104 and an accelerometer 110 may be able to detect vibrations or movements caused by the mechanical device 104. In one example, a detection environment 102 may include the cabin of a vehicle, such as the cabin of an automobile, bus, train, or airplane; or the immediate area surrounding the vehicle, such as a bicycle, motorcycle, or scooter. In another example, a detection environment 102 may include a proximity to an appliance within which magnetic field distortions and vibrations caused by the appliance can be detected by a magnetometer 108 and an accelerometer 110.

In one example, the system 100 may be configured to infer a user's mode of transportation. For example, the computing device 106 may accompany a user in-or-on a vehicle during transit from one location to another location. During movement of the vehicle, the motions of the vehicle's mechanical components, such as the vehicle's wheels, transmission, and differential, distort the earth's magnetic field. The components of a vehicle type may cause distortions to the magnetic field that may be used to identify the vehicle type. That is, the magnetic field distortions may correspond to the vehicle structure of the vehicle type (e.g., a bike chain or a car transmission system), which manifests itself as a signal for inferring a vehicle (e.g., bicycle or car) used to transport the user.

In one example, the system 100 may be configured to infer a user's in-vehicle position using vehicle position-based magnetic fields that can vary based on the computing device's location in a vehicle. The differences in the vehicle position-based magnetic fields may be sufficient to differentiate the computing device's position in the vehicle. For example, based on differences in vehicle position-based magnetic fields for a particular vehicle classification, a differentiation between a driver seat position and a passenger seat position in an automobile can be made, thereby allowing an inference of a user's position in the automobile to be made.

FIG. 2 illustrates components of an example mobile device 202 on which the present technology may be executed. In one example, the mobile device 202 may include modules 204/206/208/210 used in detecting a mechanical device. For example, the mobile device 202 may include a detection module 204, a preprocessing module 206, a feature extract module 208, a classifier module 210, and other modules. Also, the mobile device 202 may include a magnetometer 220, an accelerometer 222, as well as other sensors.

The detection module 204 may be configured to detect a mechanical device that is in proximity to the mobile device 202 using magnetometer data generated by the magnetometer 220 and accelerometer data generated by the accelerometer 222. In one example, the detection module 204 may be configured to retrieve magnetometer data from the magnetometer 220 and accelerometer data from the accelerometer 222 using a sensor framework to access the magnetometer 220 and the accelerometer 222. Illustratively, the sensor framework may provide classes and interfaces that can be used to perform a variety of sensor-related tasks. In one example, time-series magnetometer data may be retrieved from the magnetometer 220 and time-series accelerometer data may be retrieved from the accelerometer 222.

The detection module 204 may be configured to provide the magnetometer data and the accelerometer data to the preprocessing module 206 for preprocessing of the data. The preprocessing module 206 may be configured to apply a filter to the magnetometer data that filters out unwanted noise in the magnetometer data. In one example, a band-pass filter may be applied to the magnetometer data. As a specific example where magnetometer data is sampled at 100 Hz, the band-pass filter may be configured to cut-off frequencies that are at 1 Hz and 47.5 Hz. This may result in removing magnetometer data related to changes of orientation of the mobile device 202 due to vehicle movement (e.g., vehicle turns) and random noise from electronic components included in a vehicle (e.g., high frequency band noise). In one example, the preprocessing module 206 may be configured to separate the accelerometer data into a vertical component that provides vertical acceleration data and a horizontal component that provides horizontal acceleration data, as described in more detail later.

In one example, the preprocessing module 206 may be configured to convert time-series magnetometer data to frequency magnetometer data, and convert time-series accelerometer data to frequency accelerometer data. For example, the preprocessing module 206 may convert time-series data to frequency data using a FAST-Fourier Transform (FFT) method. In the case that a one-second widow is used for the time-series data, the preprocessing module 206 may perform the FFT on each one-second window of the time-series data. As a non-limiting example, the preprocessing module 206 may be configured to buffer one second of time-series data sampled using a 100 Hz sampling rate, such that a one second window contains 100 samples, and convert the 100 samples into a corresponding power spectrum. While a one-second window may provide reasonable results, as will be appreciated, different window sizes may be used, which may provide trade-offs in classification latency and classification accuracy.

In one example, after converting the time-series data to frequency data, the preprocessing module 206 may be configured to remove random noise from the frequency magnetometer data and the frequency accelerometer data. For example, the preprocessing module 206 may first apply a median filter to the frequency data, and then apply a Gaussian filter to the frequency data. The median filter may be used to remove sparse, impulse noise that may be induced from the magnetometer 220 and the accelerometer 222. The Gaussian filter may be used to remove high-frequency noise.

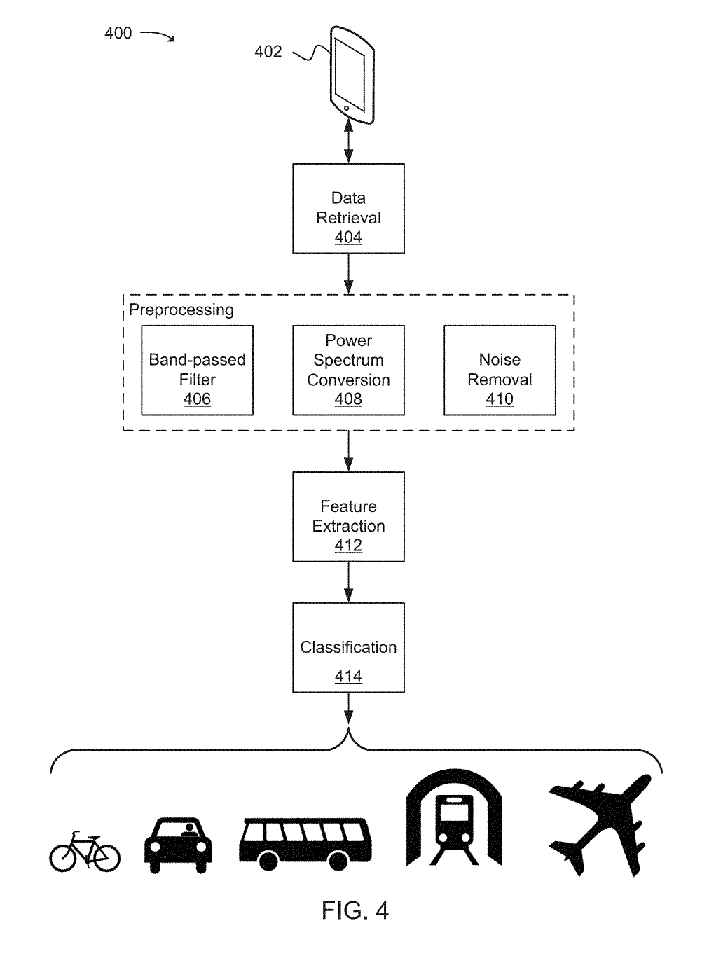

After preprocessing has been performed on the magnetometer data and the accelerometer data, the preprocessing module 206 may be configured to provide the preprocessed magnetometer data and accelerometer data to the feature extract module 208, which may be configured to extract magnetic features from the magnetometer data and acceleration features from the accelerometer data. In one example, magnetic features and acceleration features may be extracted from each corresponding FFT window output by the preprocessing module 206. One or more features may be extracted from each FFT window. Examples of features that may be extracted from the magnetometer data and the accelerometer data are provided in association with FIG. 4.

The feature extract module 208 may be configured to provide magnetic features extracted from magnetometer data and acceleration features extracted from the accelerometer data to the classifier module 210. The classifier module 210 may be configured to identify a mechanical device classification associated with the magnetic features and the acceleration features. For example, a machine learning model (e.g., a classifier) may be trained to identify a vehicle classification using a training data set of magnetic features and the acceleration features. As a non-limiting example, a two-layer classifier can be constructed. The first layer may comprise a binary classifier that uses a support vector machine to distinguish a stationary state of a vehicle from a non-stationary state of the vehicle. The second layer may comprise a voting classifier configured to distinguish a vehicle type (e.g., bicycle, car, bus, train, airplane, etc.). In one example, the second layer may include multiple classifiers configured to classify vehicle types, such that feature vectors can be applied to each classifier allowing a classification system to learn the parameters of the classifiers separately. Non-limiting examples of machine learning models that may be used by the present technology include the: Random forest classifier, Adaboost classifier, kNN (k-Nearest Neighbors) classifier, Logistic Regression classifier, Neural Network classifier, as well as other classifiers.

In one example, identifying a classification for a mechanical device may be based on a majority vote from multiple classifiers. A voting-based classification may be based on the idea that by combining classifiers, the strength and weaknesses of the classifiers may be balanced, thereby lowering bias and reducing the potential for high variance in classification results produced by a classification system. In another example, a voting-based classification may be based on a majority vote of classifications included in a time window (e.g., the last 5-10 seconds). For example, classifications generated during a time window can be inputted into a classifier configured to output a classification based on a majority vote of the classifications. After identifying a classification for a mechanical device, the classifier module 210 may be configured to output the classification for use by applications 214. For example, applications 214 that utilize a vehicle classification output by the classifier module 210 may include personal healthcare applications, life coaching applications, or recommender systems.

The various processes and/or other functionality contained within the mobile device 202 may be executed on one or more processors 216 that are in communication with one or more memory devices 218. Application components may be may be rendered on a mobile device display. The mobile device display may be a touchscreen that displays an interactive graphical user interface. The mobile device 202 may Input/Output (I/O) device communication to enable communication between hardware devices and I/O components. Networking devices may be provided for communication across a network with remote computing devices. The networking devices may provide wired or wireless networking access. Examples of wireless network access may include cellular network access, WI-FI network access, or similar network access.

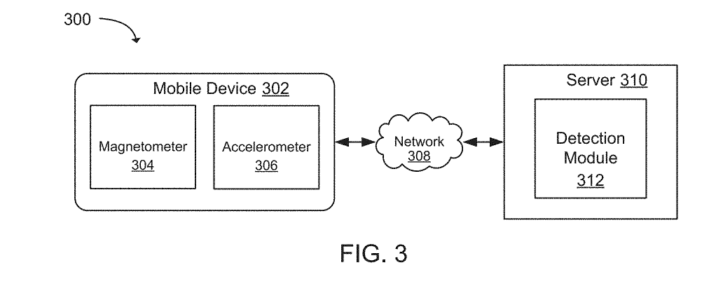

FIG. 3 is a block diagram illustrating an example system 300 for detecting a mechanical device using sensor data sent by a mobile device 302 that includes a magnetometer 304 and an accelerometer 306. In the example illustrated, the mobile device 302 may send magnetometer data generated by the magnetometer 304 and accelerometer data generated by the accelerometer 306 to a server 310. The server 310 may include a detection module 312 and other modules configured to identify a mechanical device classification as described above in association with FIG. 2.

In response to receiving the magnetometer data and accelerometer data from the mobile device 302, the server 310 (i.e., the detection module 312 and other modules) may identify a mechanical device classification that corresponds to the magnetometer data and accelerometer data. In one example, a mechanical device classification may be returned to the mobile device 302 where the mechanical device classification may be utilized by applications hosted on the mobile device 302. In another example, a mechanical device classification may be utilized by services and applications hosted on the server 310, or other servers included in a computing service environment.

In one example, the server 310 may be included in a system (e.g., a cloud computing system) that includes a number of computing devices that are arranged, for example, in one or more server banks or computer banks or other arrangements. In one example, the computing devices may support a computing environment using hypervisors, virtual machine monitors (VMMs), and other virtualization software. Communication between the mobile device 302 and the server 310, as well as various servers included in a cloud computing system may be performed using API calls, procedure calls or other network commands according to different technologies, including, but not limited to, Representational State Transfer (REST) technology or Simple Object Access Protocol (SOAP) technology. REST is an architectural style for distributed hypermedia systems. A RESTful API (which may also be referred to as a RESTful web service) is a web service API implemented using HTTP and REST technology. SOAP is a protocol for exchanging information in the context of Web-based services.

A network 308 used to transmit communications between the mobile device 302 and the server 310 may include any useful computing network, including an intranet, the Internet, a local area network, a wide area network, a wireless data network, or any other such network or combination thereof. Components utilized for such a system may depend at least in part upon the type of network and/or environment selected. Communication over the network may be enabled by wired or wireless connections and combinations thereof.

FIGS. 2 and 3 illustrate that certain processing modules may be discussed in connection with this technology and these processing modules may be implemented as computing services. In one example configuration, a module may be considered a service with one or more processes executing on a server or other computer hardware. Such services may be centrally hosted functionality or a service application that may receive requests and provide output to other services or consumer devices. For example, modules providing services may be considered on-demand computing that are hosted in a server, virtualized service environment, grid or cluster computing system. An API may be provided for each module to enable a second module to send requests to and receive output from the first module. Such APIs may also allow third parties to interface with the module and make requests and receive output from the modules. While FIGS. 2 and 3 illustrate examples of systems that may implement the techniques above, many other similar or different environments are possible. The example environments discussed and illustrated above are merely representative and not limiting.

Moving now to FIG. 4, a flow diagram illustrates an example method 400 for detecting a mode of transportation using a mobile device 402 configured with a magnetometer and an accelerometer. In one example, the magnetometer may be a Hall-effect sensor which may be used in mobile devices due to the sensor's compact size and low power consumption. The magnetic-field strength H at an arbitrary position p in space is defined by two parameters (1) r, the distance between the magnetic source and p, and (2) θ, the angle between the magnetic source's north pole and p. The field strength H can be further decomposed into two orthogonal vectors Hᵣ (the radial component at p) and H_{θ} (the tangential component at p). These two vectors form a basis in the 2D magnetic field space and their mathematical representation can be stated in terms of r and θ (where M is the magnetic moment):

Hᵣ=(M cos θ/2πr³)² (1)

H_{θ}=(M sin θ/4πr³)² (2)

Invention embodiments can leverage magnetic field variations detected by the magnetometer and extract features from the corresponding power spectrum. Equations 1 and 2 describe the trajectory of a magnetic flux when it passes through the air. The constant variable Min Eq. 1 and 2 is related to the permeability of a material that the magnetic fluxes travel through. Material having a higher permeability means that a magnetic flux can more easily flow through the material. When these magnetic fluxes flow through a ferrous media, such as metal or an external electromagnetic field, the trajectory of the magnetic fluxes are distorted due to the change in the permeability. Such distortion can be a strong interference which can be detected by a magnetometer.

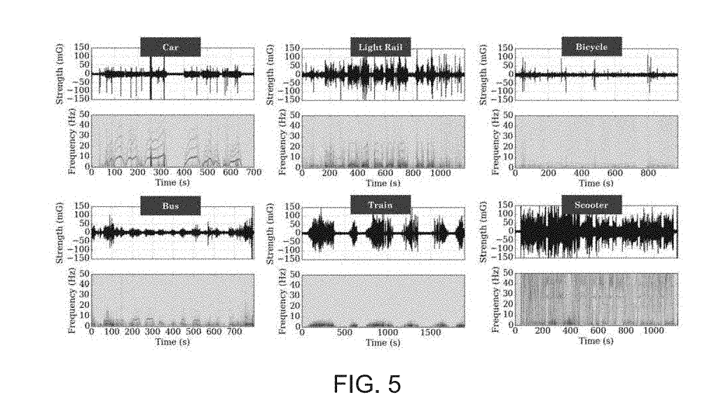

Illustratively, a motorized vehicle typically includes: an engine and alternator that generates the power to drive the main axle and the electrical components, a transmission system that regulates the gears, and a differential that adapts the car wheel rotations when making turns or moving on uneven surfaces. A hybrid vehicle typically includes: two separate engines, driven respectively by gasoline and batteries. The two engines may be regulated by a computer, and connect to a common transmission system. When a vehicle is moving, the mechanical components in the vehicle rotate synchronously and have a spin rate that corresponds to the speed of the car. When the magnetic fluxes flow through these moving metals, their trajectories are distorted harmonically with the spin rate, causing alternatively changing (AC) magnetic fields. The strength of the perceivable distorted fields is affected by the size of the moving components and how far the magnetometer is away from them. FIG. 5 shows examples of magnetic field distortion in various vehicle types. As shown, the power spectrum of each vehicle may be unique and this differentiation may be attributed to the vehicles different mechanical designs. For example, a bicycle may include a big wheel and travels at a relatively low speed, which may lead to a dominant frequency that may be lower than the other vehicles shown in FIG. 5. For vehicles that usually move at a comparable speed, such as a bus and a car, frequencies produced by the vehicles mechanical components may be in different spectrums due to the vehicle's distinct wheel sizes (e.g., the smaller wheels of a car may produce a higher frequency as compared to the larger wheels of a bus).

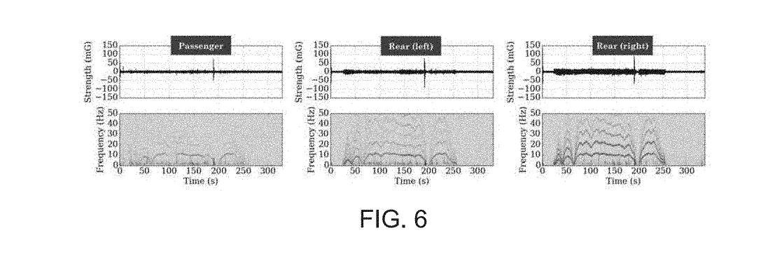

Eq. 1 and 2 show that the magnetic field decays with distance at a cubic rate. The rapid decay of the magnetic field due to different sensing distances could impact the signal quality detected by a magnetometer. FIG. 6 shows an example of field variations when a mobile device 402 having a magnetometer is placed at three different positions in a car. Namely, FIG. 6 shows magnetic field variations when a mobile device 402 is placed at three different positions: the passenger seat, the rear-left seat, and the rear-right seat of the car. FIG. 6 shows that the field strength in each position is different. In particular, the magnetic field in the passenger seat is weaker than the other two positions. In a bigger vehicle (e.g., a bus), this strength difference might become even more dramatic; in some extreme cases such as sitting in the middle of a big bus where the mobile device 402 is farther away from wheels and other rotating components, the magnetic field might become unobservable.

An accelerometer may be used to capture accelerometer data for vehicle vibrations, which may compensate for situations where the magnetic field may be week or unobservable. For example, when a vehicle is in motion, acceleration and deceleration patterns detected by an accelerometer located in a vehicle may vary according to the vehicle type. Different types of vehicles may produce unique vibration patterns (signatures) and that can be used for detecting a vehicle type. For example, a moving vehicle impacts acceleration-based signals in two manners, which may be categorized from spectrum perspectives that include a dynamic component: how a vehicle accelerates and decelerates between stationary states; and active components: vibration patterns that correlate to how a vehicle absorbs vibrations from a road or track surface.

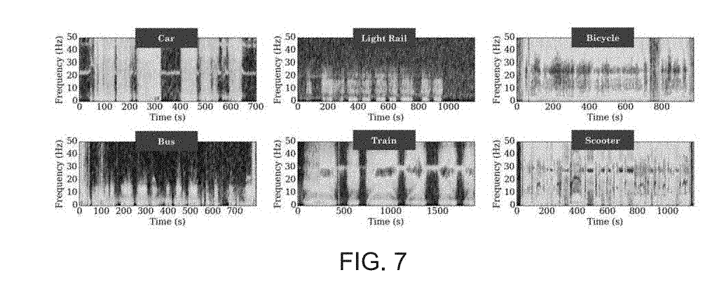

In the past, an acceleration/deceleration cycle has been used to capture a complete cycle of a vehicle speeding up and slowing down between stationary states, and thereafter, extracting features from the acceleration/deceleration cycle. This may be referred to as bagging features. Bagging features results in tens of seconds or even minutes based on different vehicle types to extract the acceleration/deceleration cycle. To avoid such delays, the present technology filters out dynamic components and uses active components as part of identifying a vehicle. Due to different suspension designs, vehicles absorb vibrations in different manners, which may manifest as unique patterns in an acceleration spectrum. FIG. 7 shows example power spectrums of vertical acceleration that correspond to FIG. 5. The vehicles shown in FIG. 7 have different abilities to absorb vibrations and bouncing force from a road based upon their suspension, which may manifest as distinctive patterns. Illustratively, FIG. 7 shows that a bicycle has strong vibrations around 20-30 Hz due to the bicycle's suspension resulting in an accelerometer detecting a strong bounce force from the road. FIG. 7 shows similar patterns for the scooter and the train. FIG. 7 shows that the car and the bus have a relatively good suspension that is able to absorb vibrations and does not produce significant high frequency energy.

Returning to FIG. 4, the method 400 illustrated combines magnetometer-based features with accelerometer-based features to detect a vehicle type that is used as a mode of transportation. As in block 404, time-series magnetometer data and time-series accelerometer data may be retrieved from the magnetometer and the accelerometer included in the mobile device 402. In one example, a sampling rate for magnetometer data and accelerometer data can be unified across different device types and manufacturers for the sake of feature extraction.

Data retrieved from the magnetometer and the accelerometer may be preprocessed prior to extracting features from the data. As illustrated, preprocessing may comprise three steps, applying a band-passed filter, converting time-series data to a power spectrum, and removing noise. For magnetometer data, as in block 406, a band-pass filter may be applied (e.g., a 5th-order Butterworth IIR (Infinite Impulse Response) filter) to the magnetometer data to ensure that features extracted from the magnetometer data is from the same range of power spectrum. As a non-limiting example, cut-off frequencies of the band-pass filter may be set to 2% and 95% of the power spectrum; given that the sampling rate is 100 Hz (that is, the usable bandwidth is 100/2=50 Hz), the cut-off frequencies are at 1 Hz and 47.5 Hz. The band-pass filter may eliminate dynamic components related to the Earth's magnetic field. For the accelerometer data, the Earth's gravity may be extracted from the accelerometer data by calculating the mean of a sliding window (e.g., a 10-second) and remove the mean from the acceleration data. Thereafter, the estimated Earth's gravity can be used to decompose the acceleration data into a vertical component and a horizontal component.

The next preprocessing step, as in block 408, involves converting the time-series magnetometer data and the time-series accelerometer data to a power spectrum. In one example, a Fast-Fourier Transform (FFT) method may be performed on each time window (e.g., a one-second time window) along the time-series data. For the time-series magnetometer data, a FFT vector can be calculated for x-/y-/z-axes respectively, and thereafter, sum up the axe's power spectrums. In doing so, the resulting frequency magnetometer data may be orientation agnostic allowing features to be extracted from the aggregated magnetic field as opposed from individual axes. For the time-series acceleration data, the vertical and horizontal components may indicate different vehicle behaviors related to how a vehicle reacts to a traveling surface (e.g., high-frequency vibrations), and therefore, features may be extracted from the vertical and horizontal components separately.

The last preprocessing step, as in block 410, removes random noise from the frequency magnetometer data and the frequency accelerometer data. For example, the frequency magnetometer data and the frequency accelerometer data may contain random noise that results from a sensor board and/or a sensing environment. In one example, random noise may be removed by applying a median filter (e.g., with a size of three), and then applying a Gaussian filter (e.g., with a sigma value of 1.2).

Having preprocessed the magnetometer data and the accelerometer data, magnetic features and acceleration features can be extracted from the spectrums in the frequency magnetometer data and the frequency accelerometer data. The magnetic features and acceleration features can be correlated to a vehicle type. Illustratively, FIG. 5 shows example frequencies that can infer a vehicle type. For example, a car may generate a dominant frequency ranging from 5-30 Hz associated with field distortions created by wheel rotations; the magnetic field of a train may be below 10 Hz and appears as white nose; a bus may be similar to a car but may be overall noisier and have dominant frequency that may be lower than a car; bicycle may generate monotone magnetic data given the bicycle's relatively simple mechanical components; and light rail may produce a dominant frequency with some white noise. Based on different suspension designs and how a vehicle absorbs surface vibrations, distinct patterns from an acceleration spectrum may be observed in the frequency magnetometer data and the frequency accelerometer data. Based on these observations, features may be extracted from each FFT window in the frequency magnetometer data and the frequency accelerometer data.

The following table provides example features that can be extracted from the frequency magnetometer data and the frequency accelerometer data.

| | | Magnetometer | | Accelerometer |
|---|---|---|---|---|
| SENSOR | | (74 features) | | (124 features) |
| FEATURES | 1 | Highest magnitude of the FFT window | 1 | Total energy of the FFT window |
| | 2 | Frequency of where highest magnitude | 2 | Energy of the 1 Hz component |
| | | is located | 3-12* | Sub-band energy |
| | 3 | Spectral entropy of the FFT window | 13-22* | Sub-band energy ration (relative to the |
| | 4 | Total energy of the FFT window | | total energy of the FFT window) |
| | 5-14* | Sub-band energy | 23-42 | Cepstral coefficients |
| | 15-24* | Sub-band energy ratio (relative to the | 43-62 | 1^{st} derivative of Cepstral coefficients |

| | | |
|---|---|---|
| | total energy of the FFT window) | *Each FFT window is divided into 10 sub-bands |
| 25-34* | Sub-band spectral entropy | (5 Hz/bin) |
| 35-54 | Cepstral coefficients | **The 62 features are extracted from the vertical |
| 55-74 | 1^{st} derivative of Cepstral coefficients | and horizontal acceleration, contributing a total of |

| | |
|---|---|
| *Each FFT window is divided into 10 sub-bands | 124 features from the accelerometer data. |
| (5 Hz/bin) | |

The table of example features shows that 198 features can be extracted from the frequency magnetometer data (74 features) and the frequency accelerometer data (124 features). The features are extracted from the power spectrum (i.e., no features are extracted from time series data). For the frequency acceleration data, the same 12 features can be extracted respectively from the vertical and horizontal components of the frequency acceleration data, yielding 24 features in total. As will be appreciated, the features shown in the table above are merely illustrative; other features may be used in connection with the present technology.

In one example, the features extracted from the frequency magnetometer data and the frequency accelerometer data may relate to a dominant frequency and magnitude, entropy, total energy and sub-band energy, Cepstral coefficients, and vibration. The dominant frequency and magnitude (power strength) may capture a wheel size and rotation speed. The dominant frequency and magnitude may contribute to identifying vehicles like cars and buses, which typically generate a strong dominant frequency in a power spectrum of frequency magnetometer data.

Entropy may describe randomness in a power spectrum. Illustratively, a scooter and light rail typically have a noisy magnetic spectrum, while a train's magnetic spectrum may be relatively less noisy. In an accelerometer power spectrum, a scooter and bicycle may be typically noisy due to a bouncing force for a surface, while vibration energy of bus may typically concentrate at a lower frequency.

Total energy may be the sum of an FFT window. A FFT window can be equally divided into 10 sub-bands (e.g., 5 Hz/sub-band) and features from each sub-band can be extracted. Sub-band energy and spectral ratio in the sub-band energy may capture fine-grained characteristics in the power spectrum. For example, with respect to a train, most energy may concentrate at below 10 Hz in the magnetic spectrums, but the energy in the case of light rail, scooter, and car usually spread out across FFT bins.

Cepstral coefficients can be used to capture a shape of FFT bins. The coefficients may be calculated by first taking the logarithm of the FFT bins and then computing the DCT (Discrete Cosine Transform) coefficients of the FFT window. For example, the 1^{st} DCT coefficient (the dynamic component) may be removed, and the 2^{nd}˜21^{th} coefficients may be retrieved. These 20 coefficients may describe the static (shape) of the FFT bins. In addition, the 1^{st}-derivative of the Cepstral coefficients (the difference between neighboring frames) may be calculated, which capture possible changes over time (i.e., the dynamic of the FFT bins). These static and dynamic cepstral coefficients may be extracted from both frequency magnetometer data and frequency accelerometer data.

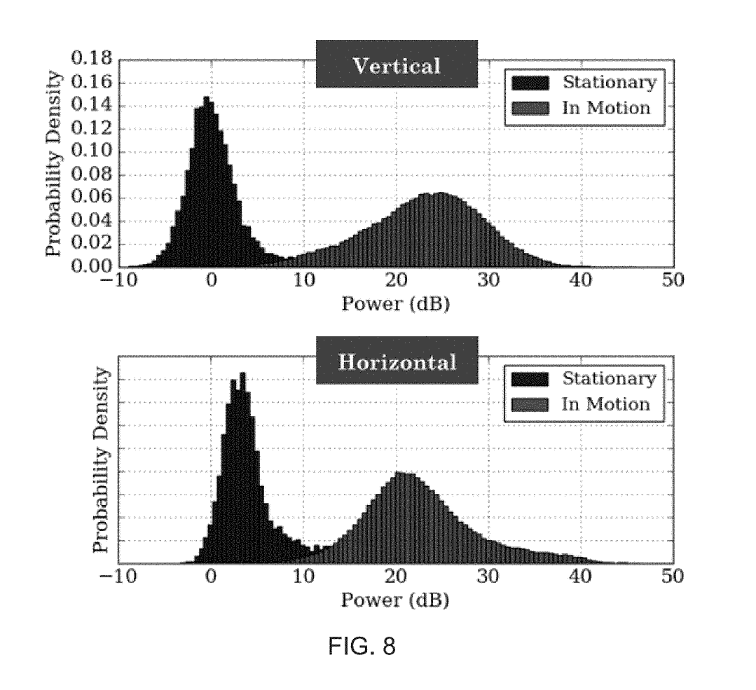

Vibration features can be extracted from vertical and horizontal components of the frequency accelerometer data. As a non-limiting example, a 1 Hz component can be extracted from both vertical and horizontal components of the frequency acceleration data. The 1-Hz component may be able to differentiate between a stationary vehicle and a vehicle that is moving. FIG. 8 shows an example of two nearly Gaussian distributions, respectively for a stationary case and an in-motion case, from a histogram of 1-Hz energy on both a vertical component and a horizontal component of frequency acceleration data.

Returning again to FIG. 4, after extracting magnetic features and acceleration features, as in block 414, classification can be performed by inputting the magnetic features and acceleration features into a classifier configured to output a vehicle classification. In one example, the classifier may be trained using magnetic features and acceleration features extracted from a historical data set. In the training phase of the classifier, a feature vector may be input into a classifier process pipeline to build the classifier.

As a non-limiting example, a two-layer classifier may be constructed and trained. The first layer of the classifier may comprise a motion detection classifier that uses a random forest model to distinguish between a stationary state (i.e., when the vehicle is not in-motion) and non-stationary states (i.e., when the vehicle is in-motion). The second layer of the classifier may comprise a transit mode classifier that uses a neural network model that classifies vehicle types (e.g., bicycle, scooter, car, bus, train (heavy rail), light rail, etc.). To avoid overfitting the model, the random forest model (the motion detection classifier) may be limited to a maximum depth and in each tree, a number of samples in leaf nodes may be constrained to avoid catching too much noise; and the number of samples may be split from an internal node to further control the tree depth. Unbalanced data among different vehicle types may be managed by applying a synthetic minority over-sampling technique, which may first calculate the distribution of the data set and generate new samples that fit the distribution.

In one example configuration, a vehicle classification may be generated by buffering subsequent vehicle classifications and generating a final vehicle classification based on a majority vote. This technique may be performed to mitigate possible random noise (e.g., noise associated with magnetometer and/or accelerometer errors, or a transition period during vehicle start/stop movement). For example, a classification can be generated based on a majority vote from a short history of vehicle classifications. As a non-limiting example, the past five, eight, ten, etc. vehicle classifications can be buffered (e.g., resulting in a 5, 8, 10, etc. second window) and a final vehicle classification can be generated based on a majority vote on the buffered vehicle classifications occurring during the window. After the classifier has been trained, the classifier may be deployed (as part of a vehicle classification system) for use on mobile devices 402 and vehicle classifications generated by the classifier can be used by applications (e.g., digital personal assistant or life coaching application) hosted on the mobile devices 402.

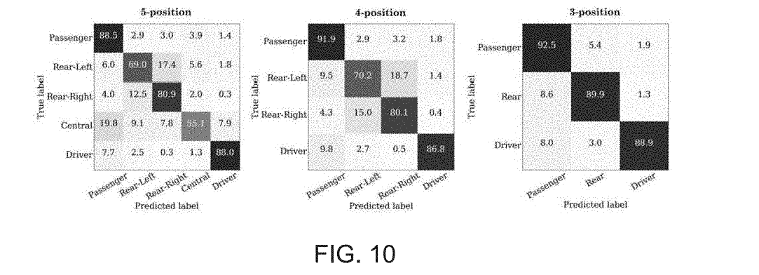

Returning to FIG. 6, in one example, a vehicle-based magnetic field can vary based on the location of a magnetometer in a vehicle. The differences in the magnetic field may be used to differentiate the magnetometer's position in a vehicle. FIG. 10 shows example confusion matrices for different vehicle configuration scenarios, illustrating that the technology described herein may be able to produce fine grained information related to a mobile device's in-vehicle position. Accordingly, in addition to generating a classification for a type of vehicle, the method described in association with FIG. 4 may be used to generate a classification for a location within a vehicle where a mobile device 402 may be located. For example, device location classification may specify a seat within a car, such as a driver's seat, a passenger seat, or a left or right rear seat. A vehicle type classification and a device location classification may be provided to applications hosted on a mobile device 402 that utilize the classifications for various purposes.

In some embodiments, information about stationary electronic devices can be ascertained by using a magnetometer, for example, in a smart phone, a wearable smartwatch or other hand held device. Many electronic devices cause a disturbance in the surrounding magnetic field, or in an electrical system to which such a device may be connected. When an electronic appliance operates at different states (e.g., different heat level of a hair dryer or different speed of a blender/food mixer), the appliance requires different amounts of power to operate at the corresponding state. Some appliances when running at different states also cause different mechanical motions inside the appliance (e.g., the changing spinning rate of a washer). These differences in how an appliance adjusts itself in a different operating status manifest themselves as distinct spectral patterns that can be sensed and extracted from a magnetometer.

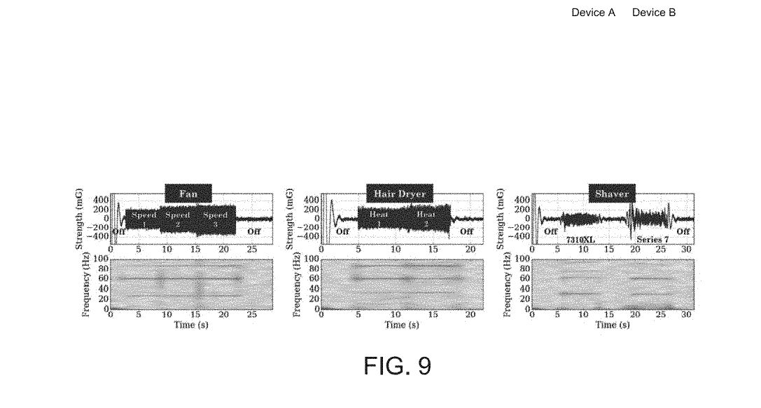

In one example, a hair dryer running at a high temperature setting consumes more power than when running at a relatively lower temperature, and generates a stronger magnetic field. Such magnetic “noise” (e.g. signature) can be used to detect in-home or other activities and how a user interacts with the user's appliances; for example, two residents in the home can use the hair dryer differently and by detecting and analyzing the magnetometer spectrum, the system can identify which resident is using the appliance and how they use it. Other appliances such as a blender or a hand-held food mixer include a DC motor. When these devices operate at a different speed, the system can infer the speed level based on the dominant frequency in the magnetic spectrum. When a person is using these motor-based appliances (e.g., stirring eggs and flour using a food mixer, or using a vacuum cleaner on different surfaces), the magnetic fields can also fluctuate during the process; for example, when the mixer hit the bowl or sticky dough, the spin rate of the blades slows down, which makes the corresponding dominant frequency smaller. These nuances can be used to detect what food the person is stirring or preparing. A magnetometer (e.g., a hall-effect sensor) may be used to identify these fine-grained appliance uses. FIG. 9 shows example magnetic field variations for when an electric fan (left) and a hair dryer (middle) operate at different states. In order to obtain the data presented in FIG. 9, the person carries a device, such as a phone or smartwatch that includes a magnetometer and uses the phone/watch to detect the magnetic fields disturbances emitted from the appliances. The magnetometer data can be first recorded and saved on the devices and afterward downloaded to a computer for processing and analysis. FIG. 9 also shows that when the appliance is operating at different states, the field strength varies with the power consumption of the state. For a portable appliance like an electric shaver (right), the fundamental frequency may be different between two models, (e.g., device A at 31 Hz and Device B at 60 Hz), although the two models produce comparable magnetic strength. Given the model features, the electric shavers may be differentiated. Beyond stationary electrical devices, such as home appliances, the magnetometer can be applied to a other scenarios, including but not limited to: 1) detecting a person's fitness status (such as exercising duration, machine type, intensity level and energy consumed) by correlating the magnetic frequency spectrum to a person's exercising effort; 2) inferring a person's proximity to a train station by examining the intensity of 60 Hz noise (or 50 Hz in Europe); or 3) sensing the potential mechanical failure of a vehicle by analyzing the abnormality in the magnetic spectrum (e.g., unusual magnetic fluctuation).

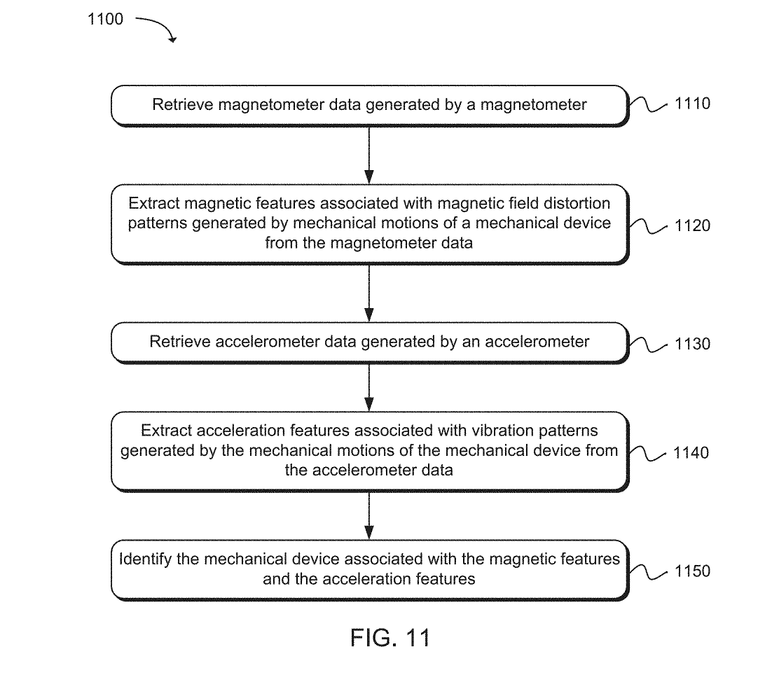

FIG. 11 is a flow diagram illustrating an example method 1100 for detecting a mechanical device. As in block 1110, magnetometer data generated by a magnetometer may be retrieved. The magnetometer may be one of a plurality of sensors included in a mobile device. The magnetometer may be configured as a hall effect sensor that detects magnetic field distortions caused by the mechanical motions of a mechanical device.

As in block 1120, magnetic features may be extracted from the magnetometer data. The magnetic features may be associated with magnetic field distortion patterns generated by the mechanical motions of a mechanical device, such a vehicle used for transportation or other mechanical devices capable of generating magnetic field distortions. In one example, prior to extracting the magnetic features, the magnetometer data may be converted from time-series magnetometer data to frequency magnetometer data and noise may be removed from the magnetometer data using one or more filters.

As in block 1130, accelerometer data generated by an accelerometer may be retrieved. Like the magnetometer, the accelerometer may be one of the plurality of sensors included in the mobile device. As in block 1140, acceleration features may be extracted from the accelerometer data. The acceleration features may be associated with vibration patterns generated by the mechanical motions of the mechanical device. In one example, prior to extracting the acceleration features, the accelerometer data may be converted from time-series accelerometer data to frequency accelerometer data and noise may be removed from the accelerometer data using one or more filters.

As in block 1150, the mechanical device associated with the magnetic features and the acceleration features may be identified. In one example, the magnetic features and the acceleration features may be input to a classifier configured to analyze the magnetic features and the accelerations features and output a classification for the mechanical device.

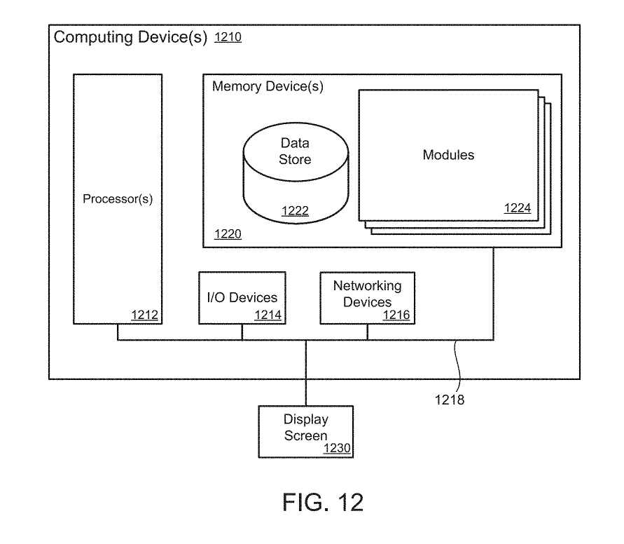

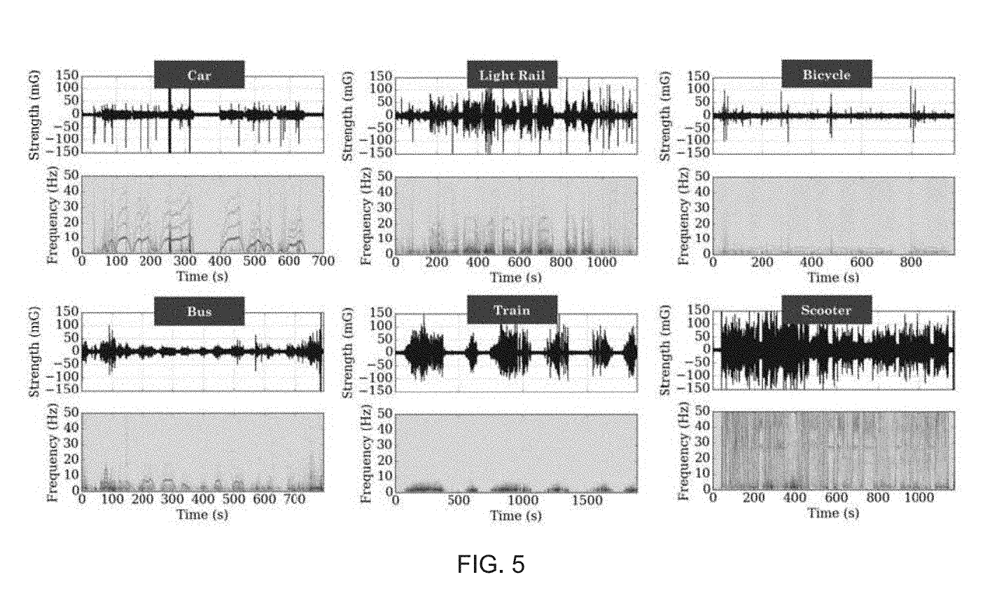

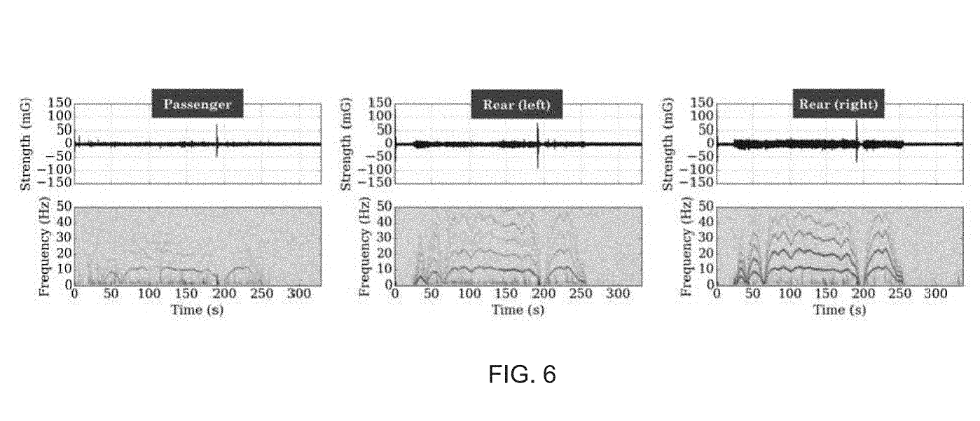

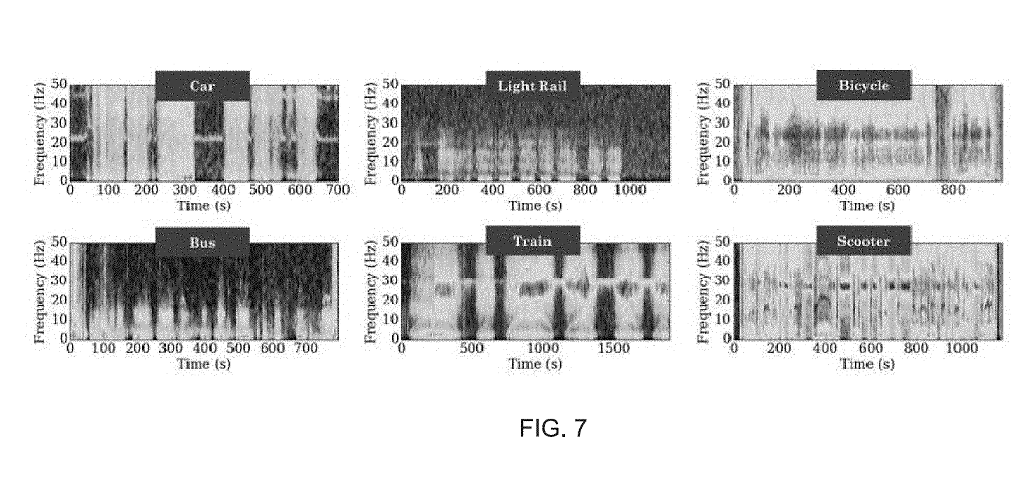

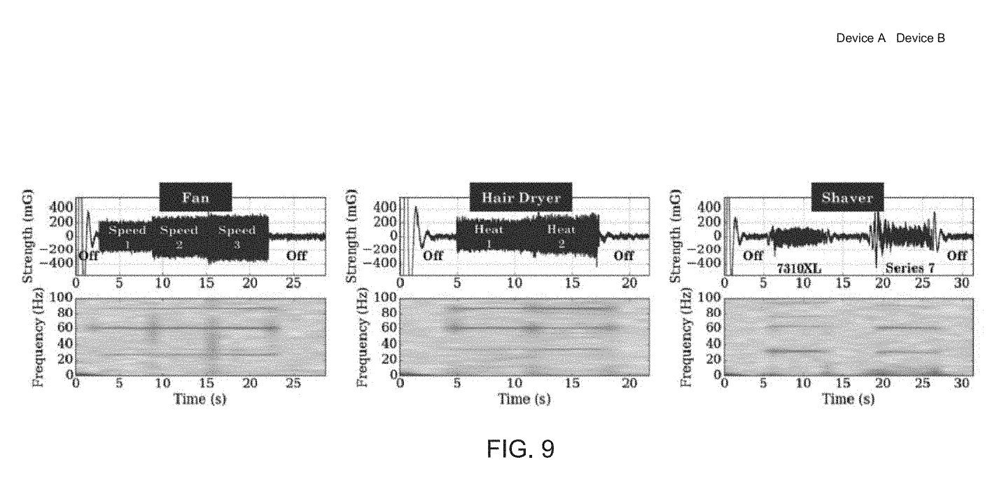

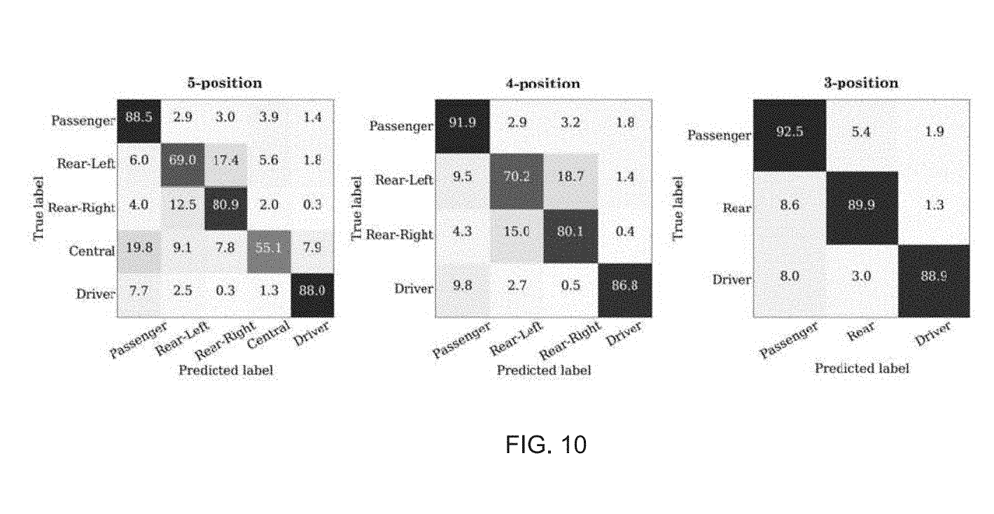

FIG. 12 illustrates a computing device 1210 on which modules of this technology may execute. A computing device 1210 is illustrated on which a high level example of the technology may be executed. The computing device 1210 may include one or more processors 1212 that are in communication with memory devices 1220. The computing device 1210 may include a local communication interface 1218 for the components in the computing device. For example, the local communication interface 1218 may be a local data bus and/or any related address or control busses as may be desired.

The memory device 1220 may contain modules 1224 that are executable by the processor(s) 1212 and data for the modules 1224. For example, the memory device 1220 can include a sensor position module and associated modules. The modules 1224 may execute the functions described earlier. A data store 1222 may also be located in the memory device 1220 for storing data related to the modules 1224 and other applications along with an operating system that is executable by the processor(s) 1212.

Other applications may also be stored in the memory device 1220 and may be executable by the processor(s) 1212. Components or modules discussed in this description that may be implemented in the form of software using high programming level languages that are compiled, interpreted or executed using a hybrid of the methods.

The computing device 1210 may also have access to I/O (input/output) devices 1214 that are usable by the computing device 1210. An example of an I/O device is a display screen 1230 that is available to display output from the computing device 1210. Other known I/O devices may be used with the computing device 1210 as desired. Networking devices 1216 and similar communication devices may be included in the computing device. The networking devices 1216 may be wired or wireless networking devices that connect to the internet, a LAN, WAN, or other computing network.

The components or modules that are shown as being stored in the memory device 1220 may be executed by the processor(s) 1212. The term “executable” may mean a program file that is in a form that may be executed by a processor 1212. For example, a program in a higher level language may be compiled into machine code in a format that may be loaded into a random access portion of the memory device 1220 and executed by the processor 1212, or source code may be loaded by another executable program and interpreted to generate instructions in a random access portion of the memory to be executed by a processor. The executable program may be stored in any portion or component of the memory device 1220. For example, the memory device 1220 may be random access memory (RAM), read only memory (ROM), flash memory, a solid state drive, memory card, a hard drive, optical disk, floppy disk, magnetic tape, or any other memory components.

The processor 1212 may represent multiple processors and the memory 1220 may represent multiple memory units that operate in parallel to the processing circuits. This may provide parallel processing channels for the processes and data in the system. The local interface 1218 may be used as a network to facilitate communication between any of the multiple processors and multiple memories. The local interface 1218 may use additional systems designed for coordinating communication such as load balancing, bulk data transfer and similar systems.

While the flowcharts presented for this technology may imply a specific order of execution, the order of execution may differ from what is illustrated. For example, the order of two more blocks may be rearranged relative to the order shown. Further, two or more blocks shown in succession may be executed in parallel or with partial parallelization. In some configurations, one or more blocks shown in the flow chart may be omitted or skipped. Any number of counters, state variables, warning semaphores, or messages might be added to the logical flow for purposes of enhanced utility, accounting, performance, measurement, troubleshooting or for similar reasons.

Some of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more blocks of computer instructions, which may be organized as an object, procedure, or function. Nevertheless, the executables of an identified module need not be physically located together, but may comprise disparate instructions stored in different locations which comprise the module and achieve the stated purpose for the module when joined logically together.

Indeed, a module of executable code may be a single instruction or many instructions and may even be distributed over several different code segments, among different programs and across several memory devices. Similarly, operational data may be identified and illustrated herein within modules and may be embodied in any suitable form and organized within any suitable type of data structure. The operational data may be collected as a single data set, or may be distributed over different locations including over different storage devices. The modules may be passive or active, including agents operable to perform desired functions.

The technology described herein may also be stored on a computer readable storage medium that includes volatile and non-volatile, removable and non-removable media implemented with any technology for the storage of information such as computer readable instructions, data structures, program modules, or other data. Computer readable storage media include, but is not limited to, non-transitory media such as RAM, ROM, EEPROM, flash memory or other memory technology, CD-ROM, digital versatile disks (DVD) or other optical storage, magnetic cassettes, magnetic tapes, magnetic disk storage or other magnetic storage devices, or any other computer storage medium which may be used to store the desired information and described technology.

The devices described herein may also contain communication connections or networking apparatus and networking connections that allow the devices to communicate with other devices. Communication connections are an example of communication media. Communication media typically embodies computer readable instructions, data structures, program modules and other data in a modulated data signal such as a carrier wave or other transport mechanism and includes any information delivery media. A “modulated data signal” means a signal that has one or more of its characteristics set or changed in such a manner as to encode information in the signal. By way of example and not limitation, communication media includes wired media such as a wired network or direct-wired connection and wireless media such as acoustic, radio frequency, infrared and other wireless media. The term computer readable media as used herein includes communication media.

Reference was made to the examples illustrated in the drawings and specific language was used herein to describe the same. It will nevertheless be understood that no limitation of the scope of the technology is thereby intended. Alterations and further modifications of the features illustrated herein and additional applications of the examples as illustrated herein are to be considered within the scope of the description.

Furthermore, the described features, structures, or characteristics may be combined in any suitable manner in one or more examples. In the preceding description, numerous specific details were provided, such as examples of various configurations to provide a thorough understanding of examples of the described technology. It will be recognized, however, that the technology may be practiced without one or more of the specific details, or with other methods, components, devices, etc. In other instances, well-known structures or operations are not shown or described in detail to avoid obscuring aspects of the technology.

### EXAMPLES

The following examples pertain to specific invention embodiments and point out specific features, elements, or steps that can be used or otherwise combined in achieving such embodiments.

In one example there is provided, an apparatus for detecting a mechanical device, the apparatus comprising one or more processors and memory configured to:

retrieve magnetometer data generated by a magnetometer;

extract magnetic features associated with magnetic field distortion patterns generated by mechanical motions of a mechanical device from the magnetometer data;

retrieve accelerometer data generated by an accelerometer;

extract acceleration features associated with vibration patterns generated by the mechanical motions of the mechanical device from the accelerometer data; and

identify the mechanical device associated with the magnetic features and the acceleration features.

In one example of an apparatus for detecting the mechanical device, the magnetometer acts as a hall effect sensor that detects the magnetic field distortions caused by the mechanical motions of the mechanical device.

In one example of an apparatus for detecting the mechanical device, the mechanical device is a vehicle used for transportation.

In one example of an apparatus for detecting the mechanical device, the one or more processors and memory are configured to convert the magnetometer data from time-series magnetometer data to frequency magnetometer data.

In one example of an apparatus for detecting the mechanical device, the one or more processors and memory are configured to convert the accelerometer data from time-series accelerometer data to frequency accelerometer data.

In one example of an apparatus for detecting the mechanical device, the one or more processors and memory are configured to remove noise from the magnetometer data and the accelerometer data using at least one filter.

In one example of an apparatus for detecting the mechanical device, the one or more processors and memory are configured to input the magnetic features and the acceleration features into a classifier trained to identify a classification associated with the magnetic features and the acceleration features.

In one example of an apparatus for detecting the mechanical device, the one or more processors and memory are configured to output the classification identified by the classifier.

In one example of an apparatus for detecting the mechanical device, the apparatus is a mobile device.

In one example of an apparatus for detecting the mechanical device, the magnetometer and the accelerometer are coupled to the mobile device.

In one example there is provided, a method of determining a mode of transportation, comprising:

retrieving magnetometer data generated by a magnetometer;

extracting magnetic features from the magnetometer data, wherein the magnetic features are associated with magnetic field distortion patterns generated by the mechanical motions of a vehicle;

retrieving accelerometer data generated by an accelerometer;

extracting acceleration features from the accelerometer data, wherein the acceleration features are associated with vibration patterns generated by mechanical motions of the vehicle;

outputting a vehicle classification that is identified using a classifier trained to identify the vehicle classification associated with the magnetic features and the acceleration features.

In one example of a method of determining a mode of transportation, vibration patterns generated by the mechanical motions of the vehicle are associated with forces related to traveling over a road or track surface that are applied to a vehicle suspension system.

In one example of a method of determining a mode of transportation, the method further comprises applying a band-passed filter to the magnetometer data to remove data related to the earth's magnetic field and dynamically changing components.

In one example of a method of determining a mode of transportation, the magnetometer data removed by the band-passed filter includes high-frequency noise.

In one example of a method of determining a mode of transportation, the method further comprises separating the accelerometer data into a vertical component that provides vertical acceleration data and a horizontal component that provides horizontal acceleration data.

In one example of a method of determining a mode of transportation, the method further comprises converting the magnetometer data and the accelerometer data from time-series data to frequency data using a Fast-Fourier Transform method.

In one example of a method of determining a mode of transportation, the method further comprises applying at least one filter to remove data related to random noise from the frequency data.

In one example of a method of determining a mode of transportation, the at least one filter includes a median filter to remove data associated with impulse noise induced by the magnetometer or the accelerometer.

In one example of a method of determining a mode of transportation, the at least one filter includes a Gaussian filter used to smooth high-frequency noise in the frequency data.

In one example there is provided, system for determining a mode of transportation, comprising

at least one processor;

a magnetometer;

an accelerometer;

a memory device including instructions that, when executed by the at least one processor, cause the system to:

retrieve time-series magnetometer data generated by a magnetometer;

convert the time-series magnetometer data to frequency magnetometer data;

analyze the frequency magnetometer data to identify magnetic features related to magnetic field distortion patterns generated by the mechanical motions of the vehicle;

retrieve time-series accelerometer data generated by an accelerometer;

convert the time-series accelerometer data to frequency accelerometer data;

analyze the frequency accelerometer data to identify acceleration features related to vibration patterns generated by the mechanical motions of the vehicle; and

identify a vehicle classification associated with the magnetic features and the acceleration features using a classifier.

In one example of a system for determining a mode of transportation, the magnetic features include: dominant frequency features, magnitude features, entropy features, total energy features, sub-band energy features, and Cepstral coefficient features.

In one example of a system for determining a mode of transportation, the acceleration features include: vibration features, dominant frequency features, magnitude features, entropy features, total energy features, sub-band energy features, and Cepstral coefficient features.

In one example of a system for determining a mode of transportation, the classifier is configured to buffer a series of vehicle classifications and determine the vehicle classification based in part on the series of vehicle classifications.

In one example of a system for determining a mode of transportation, the classifier is a two-layer classifier comprising: a motion detection classifier configured to distinguish a stationary state, and a transit mode classifier configured to distinguish a class of vehicle based in part on a majority vote based in part on buffered vehicle classifications associated with a sliding window.

In one example of a system for determining a mode of transportation, the instructions that when executed by the processor further identify a device location classification for a mobile device located in the vehicle using the magnetic features extracted from the magnetometer data.

In one example of a system for determining a mode of transportation, the device location classification identifies a seat within the vehicle where the mobile device is located.

What is claimed is:

1. An apparatus for detecting a mechanical device, the apparatus comprising one or more processors and memory configured to:
retrieve magnetometer data generated by a magnetometer;
extract magnetic features associated with magnetic field distortion patterns generated by mechanical motions of a mechanical device from the magnetometer data;
retrieve accelerometer data generated by an accelerometer;
extract acceleration features associated with vibration patterns generated by the mechanical motions of the mechanical device from the accelerometer data; and
identify the mechanical device associated with the magnetic features and the acceleration features.

2. The apparatus in claim 1, wherein the magnetometer acts as a hall effect sensor that detects the magnetic field distortions caused by the mechanical motions of the mechanical device.

3. The apparatus in claim 1, wherein the mechanical device is a vehicle used for transportation.

4. The apparatus in claim 1, further comprising one or more processors and memory configured to convert the magnetometer data from time-series magnetometer data to frequency magnetometer data.

5. The apparatus in claim 1, further comprising one or more processors and memory configured to convert the accelerometer data from time-series accelerometer data to frequency accelerometer data.

6. The apparatus in claim 1, further comprising one or more processors and memory configured to remove noise from the magnetometer data and the accelerometer data using at least one filter.

7. The apparatus in claim 1, further comprising one or more processors and memory configured to input the magnetic features and the acceleration features into a classifier trained to identify a classification associated with the magnetic features and the acceleration features.

8. The apparatus in claim 7, further comprising one or more processors and memory configured to output the classification identified by the classifier.

9. The apparatus in claim 1, wherein the apparatus is a mobile device.

10. The apparatus in claim 9, wherein the magnetometer and the accelerometer are coupled to the mobile device.

11. A computer implemented method of determining a mode of transportation, comprising:
retrieving magnetometer data generated by a magnetometer;
extracting magnetic features from the magnetometer data, wherein the magnetic features are associated with magnetic field distortion patterns generated by the mechanical motions of a vehicle;
retrieving accelerometer data generated by an accelerometer;
extracting acceleration features from the accelerometer data, wherein the acceleration features are associated with vibration patterns generated by mechanical motions of the vehicle;
outputting a vehicle classification that is identified using a classifier trained to identify the vehicle classification associated with the magnetic features and the acceleration features.

12. The method in claim 11, wherein vibration patterns generated by the mechanical motions of the vehicle are associated with forces related to traveling over a road or track surface that are applied to a vehicle suspension system.

13. The method in claim 11, further comprising applying a band-passed filter to the magnetometer data to remove data related to the earth's magnetic field and dynamically changing components.

14. The method in claim 13, wherein the magnetometer data removed by the band-passed filter includes high-frequency noise.

15. The method in claim 11, further comprising separating the accelerometer data into a vertical component that provides vertical acceleration data and a horizontal component that provides horizontal acceleration data.

16. The method in claim 11, further comprising converting the magnetometer data and the accelerometer data from time-series data to frequency data using a Fast-Fourier Transform method.

17. The method in claim 14, further comprising applying at least one filter to remove data related to random noise from the frequency data.

18. The method in claim 17, wherein the at least one filter includes a median filter to remove data associated with impulse noise induced by the magnetometer or the accelerometer.

19. The method in claim 17, wherein the at least one filter includes a Gaussian filter used to smooth high-frequency noise in the frequency data.

20. A system for determining a mode of transportation, comprising
at least one processor;
a magnetometer;
an accelerometer;
a memory device including instructions that, when executed by the at least one processor, cause the system to:
retrieve time-series magnetometer data generated by a magnetometer;
convert the time-series magnetometer data to frequency magnetometer data;
analyze the frequency magnetometer data to identify magnetic features related to magnetic field distortion patterns generated by the mechanical motions of the vehicle;
retrieve time-series accelerometer data generated by an accelerometer;
convert the time-series accelerometer data to frequency accelerometer data;
analyze the frequency accelerometer data to identify acceleration features related to vibration patterns generated by the mechanical motions of the vehicle; and
identify a vehicle classification associated with the magnetic features and the acceleration features using a classifier.

21. A system as in claim 20, wherein the magnetic features include: dominant frequency features, magnitude features, entropy features, total energy features, sub-band energy features, and Cepstral coefficient features.

22. A system as in claim 20, wherein the acceleration features include: vibration features, dominant frequency features, magnitude features, entropy features, total energy features, sub-band energy features, and Cepstral coefficient features.

23. A system as in claim 20, wherein the classifier is configured to buffer a series of vehicle classifications and determine the vehicle classification based in part on the series of vehicle classifications.

24. A system as in claim 20, wherein the classifier is a two-layer classifier comprising:
a motion detection classifier configured to distinguish a stationary state, and
a transit mode classifier configured to distinguish a class of vehicle based in part on a majority vote based in part on buffered vehicle classifications associated with a sliding window.

25. A system as in claim 20, wherein the instructions that when executed by the processor further identify a device location classification for a mobile device located in the vehicle using the magnetic features extracted from the magnetometer data.

26. A system as in claim 25, wherein the device location classification identifies a seat within the vehicle where the mobile device is located.
